(19) United States
(12) Patent Application Publication
(10) Pub. No.: US 2006/0046062 A1
(43) Pub. Date: Mar. 2, 2006

(54) Method of producing a functional film, a coating liquid for forming a functional film and a functional device

(75) Inventors: Satoshi Nishigaki, Nara-shi (JP); Emi Yamamoto, Nara-shi (JP); Kazuya Ishida, Soraku-gun (JP)

Correspondence Address: BIRCH STEWART KOLASCH & BIRCH, PO BOX 747, FALLS CHURCH, VA, 22040-0747, US

(73) Assignee: Sharp Kabushiki Kaisha

(21) Appl. No.: 11/171,380

(22) Filed: Jul. 1, 2005

(30) Foreign Application Priority Data
Aug. 31, 2004 (JP) 2004-252657

(51) Int. Cl. B29C 41/02; B29C 41/46; B29C 41/50; B32B 9/04

(52) U.S. Cl. 428/411.1; 264/101; 264/236; 264/319

(57) ABSTRACT

It is an object of the present invention to provide a method of producing a functional film, capable of simply producing a functional film which has excellent uniformity of film quality, film configuration and film thickness throughout a surface of a substrate and particularly prevents unevenness of drying along a direction of applying a coating liquid to secure uniformity at a boundary region of applying a coating liquid. The present invention is directed to a method of producing a functional film formed in a pattern form on a substrate by a wet process, the method of producing a functional film comprising the steps of: applying a solution formed by one of dissolving and dispersing a functional material in a solvent to a substrate; removing the solvent under reduced pressure; and baking the functional material under one of an inert gas atmosphere and reduced pressure in this order.

### REFERENCE TO RELATED APPLICATION

This Nonprovisional application claims priority under 35 U.S.C. § 119(a) on Patent Application No. 2004-252657 filed in Japan on Aug. 31, 2004 and the entire contents of which are hereby incorporated by reference.

### BACKGROUND OF THE INVENTION

1. Field of the Invention

The present invention relates to a method of producing a functional film, a coating liquid for forming a functional film, a functional device, an electron device and a display device. More specifically, the present invention relates to a method of producing a functional film suitable for producing a functional film such as a luminescent layer of an organic electroluminescence (EL) device and a color filter of a liquid crystal display device; a coating liquid for forming a functional film; a functional device such as an organic EL device used for a display device or a display light source; and an electron device and a display device, finely patterned.

2. Description of the Related Art

As a method of producing a functional film, a wet process using a solution of a composition formed by dissolving or dispersing a functional material in a solvent are widely used. In the wet process, a functional film is prepared by applying a solution of a composition to a substrate and then removing the solvent by heating or the like. As such a method of producing a functional film by the wet process, widely known are various printing methods such as a dip coating method, a spin coating method, a sol-gel method, a blade method, a slit coating method, a nozzle coating method, a screen printing method and an ink-jet printing method. Among others, various printing methods such as the ink-jet printing method and the screen printing method are studied as a method capable of realizing a fine patterning which is simple and highly precise, since in these printing methods, a coating liquid can be separately applied to form a functional film and the functional film can be patterned at the time of application.

Among others, the ink-jet printing method with an ink-jet printing device is widely attracts attention as a simple and fine patterning method of a functional film as shown in Japanese Kokai Publication No. 2000-323276 (p. 2, 4 and 7), Japanese Kokai Publication No. 2002-371196 (p. 2-4 and 7), Japanese Kokai Publication No. 2003-229256 (p. 2, 6and 7) and WO00/59267 (p. 34, 37 and 38).

In Japanese Kokai Publication No. 2000-323276, which is concerned with a method of producing a functional film by a conventional ink-jet printing method, disclosed is a method of producing an organic EL device forming a hole injection layer and a luminescent layer by an ink-jet printing method. In this patent, it is described that a solution of an ink composition preferably has a vapor pressure of 0.001 to 50 mmHg (room temperature) from the viewpoint of preventing clogging of a nozzle hole due to ink drying in applying a solution of an ink composition. And, it is also described that from the viewpoint of realizing a stable ejection and improving a film forming property in applying a coating liquid, a solvent of an ink composition is preferably an aprotic cyclic polar solvent. Furthermore, it is also described that a solvent having a vapor pressure of less than 0.005 mmHg is not suitable since the solvent is difficult to remove in forming a film.

And, it is described that in order to obtain a hole injection layer and a luminescent layer each having desired characteristics, the solution of an ink composition containing the above-mentioned solvent is applied by an ink-jet printing method and then the solvent is removed, and in order to obtain a hole injection layer and a luminescent layer each having an excellent function, the ink composition is preferably heat-treated after applying the ink composition by the same method. As for these operational conditions, there is a description that in Example 1 in which an ink composition containing a mixture of polyethylenedioxythiophene (PEDOT) and polyethylene sulfonate (PSS) was used as a hole injection/transport material, after applying this ink composition by an ink-jet printing method, (i) a solvent was removed in a vacuum at room temperature and then a film formed from the ink composition was heat-treated in the atmosphere at 200° C. for 10 minutes to form a hole injection layer. And, there is a description that in Example 2 in which an ink composition containing polyparaphenylene vinylene (PPV) was used as a green luminescent material, after applying this ink composition by an ink-jet printing method, (ii) a solvent was removed in a vacuum at room temperature and a film formed from the ink composition was treated in an atmosphere of nitrogen at 150° C. for 4 hours to form a luminescent layer. And, there is a description that in Example 4 in which an organic EL device is produced, after applying the ink composition used in Example 1 by an ink-jet printing method, (iii) the solvent was removed in a vacuum (1 Torr) at room temperature for 20 minutes and a film formed from the ink composition was heat-treated in the atmosphere or in an atmosphere of nitrogen at 200° C. (on a hot plate) for 10 minutes to form a hole injection layer.

In Japanese Kokai Publication No. 2000-323276, however, there is no description of problems resulting from a vapor pressure or a boiling point of a solvent, or a step of drying and of problems concerning a homogeneity and a uniformity of a film throughout an effective area of a device. Furthermore, there is no description of issues and solutions for attaining a uniform film formed from a fine droplet applied within a minute hydrophobic bank.

In Japanese Kokai Publication No. 2002-371196, with respect to a composition for forming a functional thin film which prevents a clogging or a curved flying during ejection by an ink-jet printing method and can form a uniform and homogeneous thin film, disclosed is a composition (solution) consisting of a solvent containing at least one heterocyclic compound having an oxygen atom as a constituent element and a functional material. In this publication, it is described that a boiling point of the heterocyclic compound contained in the solvent is preferably 170° C. or higher, and a vapor pressure thereof is more preferably 0.10 to 10 mmHg (at room temperature) from the viewpoint of preventing the deposition of a solute after preparing the composition and clogging of a nozzle during ejection of the solution due to a volatilization of the solvent. It is also described that from the viewpoint of preventing unevenness of film thickness or a phase separation of a content, it is preferred to reduce a pressure during or after application of the composition and a pattern formation by an ink-jet printing device or the like. Furthermore, there is a description that in Example 2, after ejecting a hole injection/transport composition (solution) containing the solvent of the heterocyclic compound described above from a head of an ink-jet printing device and applying it in a form of a pattern, (iv) the solvent was removed in a vacuum (1 Torr) at room temperature for 20 minutes and then a film formed from the a hole injection/transport composition was heat-treated in the atmosphere at 200° C. (on a hot plate) for 10 minutes to form a hole injection/transport layer. And, there is a description that in Example 3, after applying a green luminescent layer composition by an ink-jet printing device, (v) a green luminescent layer (solvent: 2,3-dihydrobenzofuran) was prepared while removing the solvent under reduced pressure (2 mmHg) and heating the composition at 60° C. Furthermore, there is a description that in Examples 4 and 5, after ejecting a blue luminescent layer composition and a red luminescent layer composition from a head of an ink-jet printing device and applying the compositions in a form of a pattern, (vi) a solvent was removed by heating the compositions at 60° C. on a hot plate to prepare a blue luminescent layer and a red luminescent layer.

In Japanese Kokai Publication No. 2002-371196, however, there is not described a step of baking a film under an inert gas atmosphere or reduced pressure after drying under reduced pressure, and technique of separating the steps of drying and baking is not disclosed.

In Japanese Kokai Publication No. 2003-229256, there is disclosed a method of manufacturing an organic EL device, in which an ink component for organic EL devices containing an organic light emitting material and at least one kind of solvent with a high boiling point of not less than 200° C. is used, for the purpose of improving flatness of an organic thin film composing a light emitting layer and mutual adhering property of films at the lamination of organic films and obtaining an organic EL device having a long life and excellent light emitting properties like stability of brightness. In this publication, it is described that in order to obtain an organic thin film having a smooth surface, after ejecting an ink, the ink is preferably heat-treated while a high boiling point solvent is still present and it is more preferred that heat treatment is performed in an atmosphere of inert gas at −15° C. to +40° C. from the glass transition temperature of the organic light-emitting material and at not more than the boiling point of the high boiling point solvent. Also, it is described that a drying condition for entirely removing the remaining solvent of a high boiling point in forming a light emitting layer is to dry a film (vii) for 5 to 10 minutes under a pressure of about 133.3 Pa (1 Torr) at room temperature in a nitrogen atmosphere. Furthermore, it is described that a temperature is above room temperature in this step is undesirable because the material used to form the light-emitting layer to heavily adhere to an upper wall surface of a bank. And, there is a description that in Examples 1 and 2, after ejecting the ink composition for organic EL devices, (vii) the ink composition was heat-treated for 30 minutes at 65° C. within a nitrogen atmosphere under atmospheric pressure and then dried to form a light-emitting layer.

In Japanese Kokai Publication No. 2003-229256, however, there is no description about technology in which a homogeneity and a uniformity of a film throughout an required area are attained by forming a functional film from the steps of applying a coating liquid, performing drying under reduced pressure and further baking the coating material under a nitrogen atmosphere or reduced pressure.

In WO 00/59267, disclosed is a composition consisting of a functional material, and a solvent comprising at least one benzene derivatives having 1 or more substituents and having 3 or more carbon atoms in this substituent as a composition, which can be used in an ink jet printing method, can use either non-polar or a weakly polar material as a function material, prevents clogging at dispensing time, achieves stable dispensing and prevents precipitation of content matter during dispensing and phase separation during film formation. It is described that as a method of manufacturing a film using this composition, from the viewpoint of preventing phase separation of the content in concentrating the composition, it is preferred that after the composition is dispensed and applied separately onto a substrate using a dispensing apparatus, (ix) it is treated at elevated temperature and then immediately an operating pressure is reduced (preferably, 20×10⁻³ mmHg) to remove the solvent. And, there is a description that as a method for manufacturing a functional device in which the composition is selectively fed and heat-treated (preferably, 40 to 200° C.) to form a luminescent material layer pattern, (x) it is preferred to reduce pressure before the composition is completely dried in the above heat treatment.

In WO 00/59267, however, after the composition undergoes the step of removing the solvent (drying) under reduced pressure, the step of baking the composition through heating is not performed.

Accordingly, in the above publications, there are disclosed various techniques to overcome the occurrence of clogging in a nozzle, which is a problem in a system in which a solution of a composition is ejected from a minute nozzle, the occurrence of film thickness unevenness and the difficulty in control of film thickness, but only problems in pixels are resolved in these solutions, which is insufficient. That is, there is no descriptions with respect to methods for resolving issues arising in securing a homogeneity, a flatness and a uniformity of a functional film throughout an area of a device, particularly in applying a coating liquid throughout an effective area of a device by repeating an application to an area of which is narrower than an effective width of a device, namely, issues, resulting from unevenness of drying along the direction of applying the coating liquid throughout a substrate, of securing uniformity at a boundary region of applying the coating liquid.

In Japanese Kokai Publication No. 2002-313566 (p. 1, 2), disclosed is a method for manufacturing an organic EL device with a film having uniform thickness on a substrate of large area, but in this method, since it is necessary to fill an apparatus or cover a surface to be coated with a solvent vapor, respectively, there was a room for contrivance to improve safeness.

Furthermore, in Japanese Kokai Publication No. 2002-182028 (p. 1, 2, 4 and 7), with respect to a method for manufacturing a color filter with an ink-jet printing system, disclosed is a method of performing a drying step of an ink receiving layer or ink under reduced pressure and then heat-treating. In Japanese Kokai Publication No. 2002-182028, however, it is described that a drying step under reduced pressure is carried out only for the purpose of reducing a process time, and a low pressure level of drying under reduced pressure is preferably within the pressure range of 133 Pa or more. Also, it is described that heat treatment is carried out only for the purpose of thermally curing. Accordingly, problems in a homogeneity or a uniformity of a functional film formed by an ink-jet printing method are unresolved.

### SUMMARY OF THE INVENTION

The present invention has been made in view of the above-mentioned state of the art and it is an object of the present invention to provide: a method of producing a functional film, capable of simply producing a functional film which has excellent uniformity of film quality, film configuration and film thickness throughout a surface of a substrate and particularly prevents unevenness of drying along a direction of applying a coating liquid to secure uniformity at a boundary region of applying a coating liquid; a coating liquid for forming a functional film; a functional device; an electron device and a display device, which can be obtained by using the method of producing a functional film and the coating liquid for forming a functional film.

The present inventors have studied a method of producing a functional film formed in a pattern form on a substrate by a wet process variously, and as a result, they have noted a step of evaporating (removing) a solvent, which is carried out after applying in a pattern form. The present inventors have found that in conventional methods, since variations in partial pressure of a vapor locally occurs on a surface of a film at a boundary area of or within patterns in a process of evaporating the solvent in a coating liquid, a functional film which is homogeneous and has a approximately consistent sectional shape throughout the whole area of applying the coating liquid is difficult to produce. In case of using a solvent which does not evaporate in a short time when left standing at room temperature, namely a solvent hard to evaporate, (for example, a solvent having a vapor pressure of 0.133 to 133 Pa at 25° C. or having a boiling point of 200 to 300° C. under atmospheric pressure) as a solvent of a coating liquid in order to avoid the above difficulty, it becomes essential to forcefully heat a droplet of the coating liquid applied to a substrate to dry (forced drying) in a drying process even though the droplet is a fine droplet of, for example, 5 to 10 picoliters. In this case, when an evaporation rate is not simultaneously controlled with high precision, a uniform and homogeneous functional film may not be obtained. Particularly when a functional film pattern becomes a high-resolution of 180 ppi (pixels per inch) or more, an area for film formation in each sub-pixel of respective colors becomes small and an amount of a coating liquid ejected becomes extremely small, and therefore this step of removing a solvent becomes important in order to produce a homogeneous and flat film. And, when a width of an area of applying a coating liquid is narrower than that for functional film formation, there is a method of forming a functional film over the whole area of applying a coating liquid by partitioning the area of applying the coating liquid into specified areas and then repeating formation of the film in the specified area. However, when this method is employed, patterns of the repeated application are observed and difference in the performance of the functional film occurs particularly at a boundary area, and this difference leads to difference in luminance, which causes unevenness of display, for example, in case of a display device.

Then, the present inventors have found that by performing the step of removing a solvent under predetermined reduced pressure prior to a step of baking after applying a coating liquid to a substrate, a uniform and homogeneous film can be formed while controlling the film configuration and the film quality, and then by performing a step of baking a functional material under an inert gas atmosphere or reduced pressure after the formation of the film, a uniform and homogeneous functional film can be produced to resolve the above issues. These findings have led to completion of the present invention.

That is, the present invention provides a method of producing a functional film formed in a pattern form on a substrate by a wet process, the method of producing a functional film comprising the steps of: applying a solution formed by one of dissolving and dispersing a functional material in a solvent to a substrate; removing the solvent under reduced pressure; and baking the functional material under an inert gas atmosphere in this order.

The present invention also provides a method of producing a functional film formed in a pattern form on a substrate by a wet process, the method of producing a functional film comprising the steps of: applying a solution formed by one of dissolving and dispersing a functional material in a solvent to a substrate; removing the solvent under reduced pressure; and baking the functional material under reduced pressure in this order.

Furthermore, the present invention also provide a coating liquid for forming a functional film, formed by one of dissolving and dispersing a functional material in a solvent, wherein the solvent contains at least one organic solvent with an aromatic ring having a vapor pressure of 0.133 Pa or higher and 133 Pa or lower at 25° C.

And, the present invention also provide a coating liquid for forming a functional film, formed by one of dissolving and dispersing a functional material in a solvent, wherein the solvent contains at least one organic solvent with an aromatic ring having a boiling point of 200° C. or higher and 300° C. or lower under atmospheric pressure.

### BRIEF DESCRIPTION OF THE DRAWINGS

FIG. 1(a) is a schematic front view showing a basic planar structure of a display device and an optical device. FIG. 1(b) is a schematic sectional view showing a basic sectional structure of a display device. FIG. 1(c) is a schematic sectional view showing a basic sectional structure of an optical device.

FIG. 2(a) shows schematically a state of applying a solution of a composition using an ink-jet printing device, and FIG. 2(b) is a cross sectional view schematically showing a color filter substrate shown in FIG. 2(a), taken on line A-A′, and showing a state in which a solvent having a high vapor pressure is applied to the substrate.

FIG. 3(a) is a schematic front view showing a photoluminescence (PL) pattern of a functional film prepared by a conventional method of producing a functional film. FIG. 3(b) is a schematic front view showing a photoluminescence (PL) pattern of a functional film prepared by a method of producing a functional film of the present invention.

### EXPLANATION OF NUMERALS AND SYMBOLS

10: Substrate

11: Bank

12: Electro-optic functional film

13a, 13b: Electrodes

15a: Droplet applied to a central portion of a substrate

15b: Droplet applied to an edge portion of a substrate

16: Droplet

17: Vapor of a solvent

22: Optical functional film

30: Ink-jet head

32: Photoluminescence (PL) pattern

42: PL pattern (portion having thicker film thickness than that of 43)

43: PL pattern (portion having thinner film thickness than that of 42)

### DETAILED DESCRIPTION OF THE PREFERRED EMBODIMENTS

A method of producing a functional film of the present invention is a method of producing a functional film formed in a pattern form on a substrate by a wet process. The wet process generally refers to a method of producing a functional film using a solution obtained by dissolving or dispersing (suspending) a material for a functional film in an appropriate solvent. Therefore, the wet process referred to herein is not particularly limited and includes various printing methods such as a dip coating method, a spin coating method, a sol-gel method, a blade method, a slit coating method, a nozzle coating method, an ink-jet printing method, and a screen printing method. Among others, the ink-jet printing method and the screen printing method are preferred from the viewpoint of being capable of applying a coating liquid separately and patterning in applying a coating liquid. The above-mentioned substrate is not particularly limited and includes a substance consisting of inorganic materials such as quartz, soda glass, ceramic materials and the like or organic materials such as polyimide, polyester and the like. The above-mentioned functional film extensively refers to films which generally exhibit functions utilizing mechanical, thermal, chemical, optical, electrical and bionic properties by some stimulus. Accordingly, the functional film referred to herein is not particularly limited and includes, for example, a luminescent layer of an organic electro luminescence (EL) device, a color filter layer of a liquid crystal display device and a wiring film of a wiring substrate.

The above-mentioned method of producing a functional film comprises the steps of applying a coating liquid, removing a solvent (drying step) and baking a functional material in this order.

In the above-mentioned step of applying a coating liquid, a solution formed by dissolving or dispersing a functional material in a solvent is applied to a substrate. As a method of applying a solution, used may be various printing methods exemplified in the description of the wet process. In addition, the step of applying a coating liquid is generally carried out under atmospheric pressure. In the present invention, a solution to form a functional film is applied in a pattern form to a substrate in the step of applying a coating liquid.

Examples of a functional material contained in the solution applied include an organic EL material, a ferroelectricmaterial, a conductive material, an insulating material, a semiconductor material and a coloring material such as a dye and a pigment. A solvent of the solution is not particularly limited as long as it can dissolve or disperse a functional material. Examples of a solvent which may be used in the present invention are shown in the following Table 1. In Table 1, vapor pressures and boiling points of the solvents described in literatures are cited and shown, and when these values are within the range suitable for the present invention, a mark “◯ (excellent)” was given and when they are out of the range, a mark “× (poor)” was given. The range suitable for the present invention is a range that with respect to a vapor pressure, a vapor pressure at 25° C. is 0.133 Pa (0.001 mmHg) or higher and 133 Pa (1 mmHg) or lower and with respect to a boiling point, a boiling point under atmospheric pressure is 200° C. or higher and 300° C. or lower.

TABLE 1

| Solvents | Synonyms | Vapor pressure | | Boiling point | |
|---|---|---|---|---|---|
| 1,3,5-TRIETHYL- | | — | (∘) | 215° C. | ∘ |
| BENZENE | | | | | |
| 1,2,3,4- | TETRALIN | 0.368 mmHg at 25° C. | ∘ | 207° C. | ∘ |
| TETRAHYDRO- | | 0.18 mmHg at 20° C. | | 207.65° C. | |
| NAPHTHALENE | | | | | |
| CYCLOHEXYL- | | — | | 239° C. | |
| BENZENE | | 1 mmHg at 67.5° C. | ∘ | 240.12° C. | |
| 1,2,4- | PSEUDO- | 2.1 mmHg at 25° C. | x | 168° C. | x |
| TRIMETHYL | CUMENE | 1.7 mmHg at 20° C. | | 169° C. | |
| BENZENE | | | | | |
| 1,3,5- | MESITYLENE | 0.25 kPa at 2° C. | x | 165° C. | |
| [symbol] | | 1.9 mmHg at 20° C. | | | |
| (TRIMETYLBENZENE) | | 10 mmHg at 48.82° C. | | 164.7° C. | |
| DECAHYDRO- | | 2.3 mmHg | x | trans 187° C. | |
| NAPHTHALENE | | | | cis 196° C. | |
| 1,2,4,5- | DURENE | 160 mmHg at | (∘) | 196-197° C. | Δ |
| TETRAMETHYL- | | 140° C. | | | |
| BENZENE | | | | | |
| p-CYMENE | 1-METHYL-4- | 1.0 mmHg at 17.3° C. | x | 176-178° C. | x |
| | ISOPROPYL- | 1.5 mmHg at 25° C. | | 177.1° C. | |
| | BENZENE | | | | |
| CUMENE | ISOPROPYL- | 8.0 mmHg at 20° C. | x | 152-154° C. | x |
| | BENZENE | | | | |
| DIISOPROPYL- | | 0.25 mmHg at 25° C. | ∘ | 770-82.0° C. | ∘ |
| BENZENE | | | | at 10 mmHg | |
| | | — | | — | |
| 1,4-DIISOPROPYL- | | 0.25 mmHg at 2° C. | ∘ | 203° C. | ∘ |
| BENZENE | | | | | |
| 1,3-DIISOPROPYL- | | — | (∘) | 203° C. | ∘ |
| BENZENE | | | | | |
| 1,3,5-TRIISO- | | — | (∘) | 232.0-236.0° C. | ∘ |
| PROPYLBENZENE | | | | | |
| DODECYL- | 1-PHENYL- | <10 Pa at 20° C. | ∘ | 290-410° C. | x |
| BENZENE | DODECANE | <0.075 mmHg at 20° C. | | | |
| (mixture of | | 6 mmHg at 172° C. | | 331° C. | |
| isomer) | | | | | |
| ANISOLE | METHOXY- | 10 mmHg at 42° C. | (x) | 156° C. | x |
| | BENZENE | 20 mmHg at 55.8° C. | | 153.75° C. | |
| DIPHENYL- | | 0.008 mmHg at 25° C. | ∘ | 265° C. | ∘ |
| METHANE | | | | | |
| DIPHENYL | | — | | 258.3° C. | ∘ |
| ETHER | | 0.0225 mmHg at 25° C. | ∘ | 259° C. | ∘ |
| ETHYL PHENYL | | — | (∘) | 204-205° C. | ∘ |
| SULFIDE | | | | | |
| PHENYL | DIPHENYL | 0.00754 mmHg at 25° C. | ∘ | 295° C. | |
| SULFIDE | SULFIDE | | | | |
| XYLENE | | 21 mmHg | x | 140° C. | x |
| 1,2,3,4- | PREHNITENE | 11 mmHg at 80° C. | ∘ | 203° C. | ∘ |
| TETRAMETHYL- | | 0.361 mmHg at 25° C. | | 205° C. | |
| BENZENE | | | | | |

In the above-mentioned step of removing a solvent, a solvent is removed under reduced pressure. A pressure during reduced pressure in the step of removing a solvent is preferably 0.133 Pa or higher and 1332 Pa or lower. In the step of removing a solvent according to the present invention, a uniform and homogeneous film can be formed by removing a solvent in a solution while controlling the film configuration and the film quality. The above-mentioned step of baking a functional material is either of (i) a step of baking a functional material under an inert gas atmosphere or (ii) a step of baking a functional material under reduced pressure. Inert gas used in the step of baking of (i) is not particularly limited and includes, for example, nitrogen gas, neon gas and argon gas. A pressure under reduced pressure used in the step of baking of (ii) is preferably 1.33 Pa or lower. It is preferred that after the step of removing a solvent from a coating liquid under reduced pressure by which an evaporation rate is controlled, a functional material is baked at an optimal temperature depending on the kind of functional material in order to exhibit functions of the functional material. In the present invention, functions of a functional material in the film can be sufficiently exhibited and a uniform and homogeneous functional film can be produced by heat-treating a film formed in the step of removing a solvent in the baking steps of (i) or (ii). The step of baking a functional material may be or not may be accompanied by a chemical reaction, but the step of baking is different from a step of thermally curing which only cures a thermosetting resin because of mainly being aimed at exhibiting functions of a functional material. And as for the step of baking, the step of (ii) is particularly suitable, since a temperature of heat treatment for exhibiting functions may be reduced and a functional film of higher performance may be formed when this step is performed under reduced pressure.

The method of producing a functional film of the present invention may comprise or may not comprise an other step as long as it comprises the steps of applying a coating liquid, removing a solvent and baking a functional material of the above (i) and (ii) as an essential step and is not particularly limited.

Hereinafter, effect of the present invention will be described in detail.

In the method of producing a functional film, a homogeneity and a uniformity of a functional film depends on a homogeneity and a uniformity of a dry film before baking. In order to form a film from a solution of a functional material and to obtain a film having a patterned microstructure, while maintaining a state of dissolving or dispersing the functional material isotropically and homogeneously in a solvent, (A) physical properties of a solvent and (B) a step of removing the solvent before forming a dry film are important. Specifically, in order to realize a state that the functional material is diffused isotropically and homogeneously in the solvent in the film having a microstructure, the solvent is preferably removed in a state of suppressing a thermal disturbance to a minimum and it is necessary to remove the solvent under reduced pressure.

For example, when a droplet of an ink a solution of composition containing an organic solvent with a low vapor pressure or a solvent with a high boiling point is ejected and applied to a substrate, the solvent does not evaporate in a short time when left standing at room temperature even though the droplet is a fine droplet of, for example, 5 to 10 picoliters. In this case, when the droplet is forcefully heated to dry in a state in which a large amount of the solvent remains, a homogeneous and flat film is not obtained. Particularly when a functional film pattern becomes a high-resolution of 180 ppi or more, an area for film formation in each sub-pixel of respective colors becomes small and an amount of ink ejected becomes extremely small, and therefore the step of removing a solvent becomes more important in order to obtain the homogeneous and flat film. And so, drying under reduced pressure at a pre-baking temperature as close to room temperature as possible is effective for forming a thin film (film thickness; 50 to 100 nm) of an organic luminescent layer having a good film-forming property under good control, and desired thickness and shape of the film are first determined in this step of removing a solvent. And an organic EL device, having a luminescent layer prepared by thus forming a film (applying /drying under reduced pressure) and then baking the functional material under an inert gas atmosphere or reduced pressure, can obtain characteristics of high efficiency and long life.

And, for example, by performing drying under reduced pressure at temperatures from room temperature to 60° C. to form films of respective color materials, it is possible to inhibit an organic luminescent material from being pulled toward a surface of an isolating wall (bank) provided with hydrophobicity to form a film there preferentially. And, by effectively forming a film at an effective luminescent area in a sub-pixel, a flat film having a desired film thickness can be formed with a smaller amount of droplet.

Hereinafter, a preferred embodiment in the method of producing a functional film of the present invention will be described in detail.

Preferably, the above solvent contains at least one organic solvent with an aromatic ring having (a) a vapor pressure of 0.133 Pa (0.001 mmHg) or higher and 133 Pa (1 mmHg) or lower at 25° C., and/or, (b) a boiling point of 200° C. or higher and 300° C. or lower under atmospheric pressure. When such solvent is used, air drying of the solvent under atmospheric pressure after the step of applying a coating liquid can be effectively controlled and differences in film thickness and film quality caused by difference in position of applying a coating liquid on a substrate can be sufficiently reduced. In order to control the occurrence of defects such as an unevenness of a film resulting from a time lag between start of application and end of application, the elicitation of a junction between patterns in applying a coating liquid to a plurality of blocks divided, and a non-flatness or an unevenness of each film having microstructure in forming a pattern utilizing hydrophilic-hydrophobic contrast, a very small amount of a solution of a composition containing a solvent having physical properties of a high boiling point or a low vapor pressure not to easily evaporate at room temperature may be preferably used. For example, when several tens to several hundreds picoliters of a solution of a composition containing a solvent for forming a film having a microstructure is applied, a solvent having a vapor pressure of several hundreds Pa or higher at room temperature (25° C.) evaporates in a short time after applying the solution of a composition in the case, and therefore a solvent having a vapor pressure of several hundreds Pa or lower is preferably used. In addition, there is an empirical rule of the following equation (1) between a vapor pressure vp (at 25° C.) and a boiling point bp of a solvent, and from this equation, it can be estimated that a vapor pressure at 25° C. of, for example, a solvent having a boiling point of 200° C. is about 0.5 mmHg.
vp=2092.3 e^{-0.0419bp} (1)

Examples of an organic solvent having the above properties include 1,3,5-triethylbenzene (a boiling point under atmospheric pressure; 215° C.), tetralin (49.1 Pa, 207° C.), prehnitene (48.1 Pa, 205° C.), cyclohexylbenzene (240.1° C.), diisopropylbenzene (33.3 Pa, 204 to 207° C.), diphenylmethane (1.07 Pa, 265° C.), diphenyl ether (3.00 Pa, 259° C.), ethyl phenyl sulfide (204 to 205° C.) and phenyl sulfide (1.01 Pa, 295° C.). When these organic solvents are used, these organic solvents may be used singly or in combination with two or more of them or may be used in combination with an other organic solvent other than the organic solvent having the above properties. In addition, the solvent preferably contains at least one organic solvent with an aromatic ring having (a) a vapor pressure of 0.133 Pa or higher and 133 Pa or lower at 25° C., and/or, (b) a boiling point of 200° C. or higher and 300° C. or lower under atmospheric pressure in an amount of 20% by volume or more with respect to the total solvent. More preferably, the organic solvent contained in the solvent has a vapor pressure of 0.5 Pa or higher and 50 Pa or lower at 25° C. and a boiling point of 240° C. or higher and 295° C. or lower under atmospheric pressure.

The above-mentioned substrate is preferably provided with a hydrophilic-hydrophobic contrast pattern. And, the above-mentioned substrate is preferably provided with a pattern partitioned with an isolating wall and the isolating wall is hydrophobic and inside of the pattern partitioned with the isolating wall is hydrophilic. When such substrate is used, a functional film having a microstructure consisting of a highly precise pattern can be formed over a wide area by a simple wet process. Configurations of the hydrophilic-hydrophobic contrast pattern and the pattern partitioned with the isolating wall (an isolating wall pattern) are appropriately designed depending on a configuration of a minute pattern of a functional film to be produced. The hydrophilic-hydrophobic contrast pattern is not particularly limited as long as it is a pattern having hydrophilicity (an affinity with the solution formed by one of dissolving and dispersing a functional material in a solvent) at an area forming a functional film on a substrate and hydrophobicity at an area not forming a functional film on a substrate. As a method of imparting hydrophilicity to the substrate and/or the inside partitioned with the isolating wall, mentioned may be UV ozone treatment and oxygen plasma treatment. Also, as a method of imparting hydrophobicity to the substrate and/or the isolating wall, a plasma treatment using fluorine-based gas (gaseous substance comprising a fluorine atom) such as carbon tetrafluoride and the like maybe mentioned. Examples of a configuration of the substrate provided with the isolating wall pattern include a configuration of providing a pattern of a bank (a protrusion, a projection) on the substrate and a configuration of providing a pattern of a groove (a depression) on the substrate. A material of the bank includes photosensitive resins comprising polyimide resin, acrylic resin, novolac resin and the like, and a method of forming the pattern of a bank includes a photolithography process including a series of steps such as application of a resin material, pre-baking, exposure, developing and post-baking. A method of forming the pattern of a groove includes various dry-etching methods and various wet-etching methods. A shape and a dimension of the bank and groove are not particularly limited.

In the above-mentioned substrate, the shortest interval (spatial period) of the hydrophilic-hydrophobic contrast patterns and/or of the patterns partitioned with the isolating wall is preferably 25 μm or larger and 50 μm or smaller. By forming a pattern with such fine spacing, a highly precise display device of 180 ppi or higher can be produced, for example, in a full color display device. The shortest interval of the hydrophilic-hydrophobic contrast patterns and/or of the patterns partitioned with the isolating wall is more preferably 28 μm or larger and 42 μm or smaller.

The above-mentioned step of applying the solution is a step in which the solution is applied with an ink-jet printing device and a minimum amount of an ejected droplet of the solution applied is preferably 2 picoliters or more and 10 picoliters or less. By applying the solution using an ink-jet printing device, it is possible to separately apply the solution to form a functional film and to perform a highly precise and fine patterning with ease in applying the solution. And, in order to perform such a highly precise and fine patterning, an amount of a minimum unit (a droplet) of the solution ejected from a nozzle is preferably small. When a minimum amount of an ejected droplet of the solution applied exceeds 10 picoliters, a uniform and homogeneous functional film pattern may not be formed due to interference between coating liquids between pattens even though the hydrophilic-hydrophobic contrast pattern and/or the pattern partitioned with the isolating wall is formed on a substrate. The minimum amount of an ejected droplet of the solution applied with an ink-jet printing device is more preferably 3 picoliters or more and 8 picoliters or less.

The above-mentioned step of removing the solvent is preferably carried out in a vacuum of 13.3 Pa (0.1 mmHg) or higher and 1332 Pa (10 mmHg) or lower and at a treatment temperature of 20° C. or higher and 60° C. or lower. When the step is carried out under such conditions, defects such as heterogeneous and uneven of a film, which have arisen in a conventional step of removing a solvent, can be more effectively controlled. Furthermore, when the treatment temperature is higher than 60° C. or the vacuum is lower than 13.3 Pa, a surface of the film may becomes rough or a flatness of the film may not be secured. On the contrary, when the treatment temperature is lower than 20° C. or the vacuum is higher than 1332 Pa, an effect of the present invention may be insufficiently obtained. The treatment temperature is more preferably 25° C. or higher and 50° C. or lower and the vacuum is more preferably 66.5 Pa or higher and 666 Pa or lower.

The above-mentioned step of baking the functional material under an inert gas atmosphere is preferably carried out at a treatment temperature of 100° C. or higher and 200° C. or lower. And, the above-mentioned step of baking the functional material under reduced pressure is preferably carried out at a treatment temperature of 80° C. or higher and 150° C. or lower. When the functional material is baked within such a temperature range, functions of the functional material can be sufficiently exhibited, for example, in producing a functional film using a solution containing an organic solvent having a boiling point of 200 to 300° C. When the solution of a composition contains a precursor of a functional material, a functional film consisting of a desired functional material may be obtained by proceeding a reaction of thermal crosslinking and the like. Furthermore, in the step of baking the functional material under reduced pressure, since a treatment temperature maybe decreased, a function of the functional material may be particularly effectively exhibited. The above-mentioned step of baking the functional material under an inert gas atmosphere is more preferably carried out at a treatment temperature of 120° C. or higher and 180° C. or lower. And the step of baking the functional material under reduced pressure is more preferably carried out at a treatment temperature of 100° C. or higher and 130° C. or lower.

The present invention also provide a coating liquid for forming a functional film, formed by one of dissolving and dispersing a functional material in a solvent, wherein the solvent contains at least one organic solvent with an aromatic ring having a vapor pressure of 0.133 Pa or higher and 133 Pa or lower at 25° C. The present invention also relates to a coating liquid for forming a functional film, formed by one of dissolving and dispersing a functional material in a solvent, wherein the solvent contains at least one organic solvent with an aromatic ring having a boiling point of 200° C. or higher and 300° C. or lower under atmospheric pressure. When these coating liquids for forming a functional film are used, a solvent can be removed under sufficient control as described above and a flatness of a film (a film having a coating structure) in a micro-area can be improved, and variations in film thickness within a film and between films can be effectively reduced, and therefore the coating liquid is suitable for producing a functional film, particularly for the method of producing a functional film according to the present invention in which a solvent is removed under control by the drying under reduced pressure. In addition, the solvent preferably contains at least one organic solvent with an aromatic ring having (a) a vapor pressure of 0.133 Pa or higher and 133 Pa or lower at 25° C., and/or, (b) a boiling point of 200° C. or higher and 300° C. or lower under atmospheric pressure in an amount of 20% by volume or more with respect to the total solvent. More preferably, the organic solvent contained in the solvent has a vapor pressure of 0.5 Pa or higher and 50 Pa or lower at 25° C. and a boiling point of 240° C. or higher and 295° C. or lower under atmospheric pressure.

The present invention also provides a functional film produced by the above-mentioned method of producing a functional film, and a functional device provided with the functional film formed by using the above-mentioned coating liquid for forming a functional film. When the functional device of the present invention is used, since a uniform and homogeneous functional film is produced throughout the whole area applied the coating liquid by using the above-mentioned method of producing a functional film and the above-mentioned coating liquid for forming a functional film, occurrence of difference in performance of the functional film in each area is prevented and functions of the film can be sufficiently exhibited. The above functional device is not particularly limited and includes, for example, display devices such as an organic EL device and optical devices such as a color filter.

The present invention also provides an electron device formed by mounting the functional device. In the present invention, since a functional film finely patterned can be uniformly and homogeneously formed, a highly reliable electron device having an excellent function can be produced. The electron device is not particularly limited as long as it is one of various components of an electronic circuit and includes, for example, a transistor, a diode, IC (integrated circuit) and the like.

The present invention also provides a display device formed by mounting the functional device. In the present invention, since a functional film finely patterned can be uniformly and homogeneously formed, a highly reliable display device having excellent display quality can be produced. As the display device, an organic EL display device and the like may be mentioned.

In the method of producing a functional film according to the present invention, since a solvent is removed from a coating liquid applied under reduced pressure, a dry film can be formed while controlling a film configuration and a film quality, and then by baking the dry film, a uniform and homogeneous functional film can be simply produced throughout a surface of a substrate.

When the coating liquid for forming a functional film of the present invention is used, a solvent can be removed under sufficient control and a flatness of a film (a film having a coating structure) in a micro-area can be improved, and variations in film thickness within a film and between films can be effectively reduced.

<Structures of a Display Device and an Optical Device>

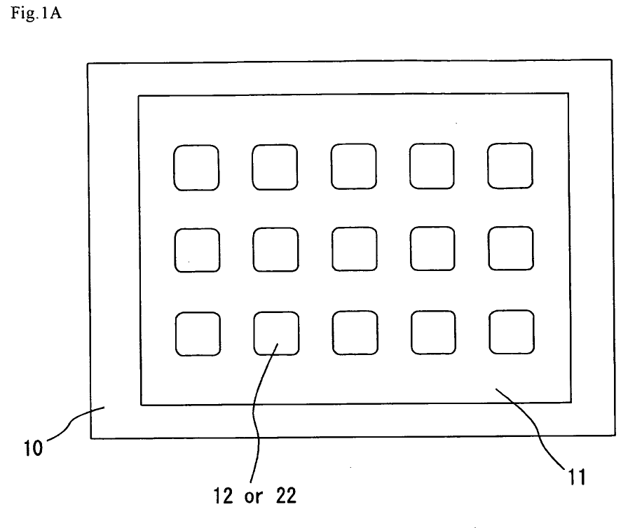

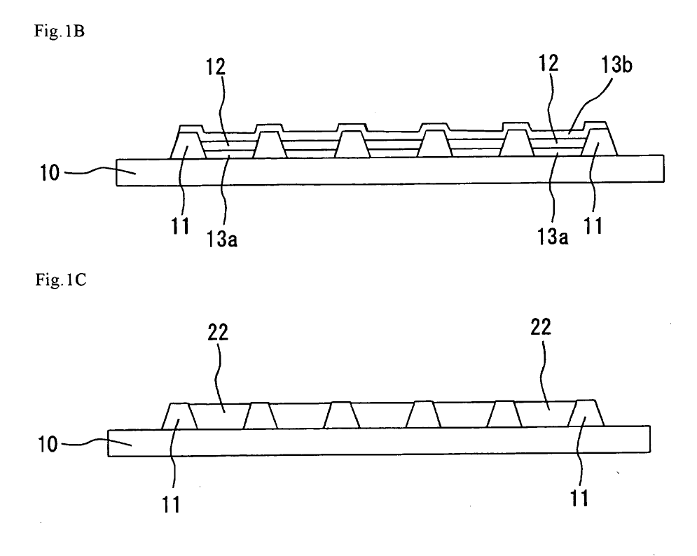

FIG. 1(a) is a schematic front view showing a basic planar structure of a display device and an optical device. FIG. 1(b) is a schematic sectional view showing a basic sectional structure of a display device. FIG. 1(c) is a schematic sectional view showing a basic sectional structure of an optical device.

In case of the display device, as shown in FIG. 1(b), the supporting substrate 10 to support the entire device, the isolating wall 11 provided in a pattern form on the supporting substrate 10, the electro-optical functional film 12 formed between the isolating walls 11, and the electrodes 13a, 13b provided to electro-optically operate the electro-optical functional film 12.

In case of the optical device, as shown in FIG. 1(c), the supporting substrate 10 to support the entire device, the isolating wall 11 provided in a pattern form on the supporting substrate 10, the optical functional film 22 formed between the isolating walls 11. An electrode is not shown in FIG. 1(c), but a transparent electrode is required on the optical functional film 22, for example, in applying the optical device as a color filter substrate used for a display device. In these Figures, an example of forming the isolating wall 11 is shown, but the hydrophilic-hydrophobic contrast pattern may be formed in a state of being flat without physical projections and depressions.

A material of the substrate 10 is not particularly limited and heretofore known materials used in display devices or optical devices may be used. Examples of such a material of substrate include an inorganic material such as quartz, soda glass, ceramic materials and the like, or an organic material such as polyimide, polyester and the like. A material of the electrode is not particularly limited but one of the electrodes consists of a transparent material in the display device. A material of the transparent electrode is not particularly limited and heretofore known materials used in display devices maybe used, and in case of, for example, an organic EL (electroluminescence) device, thin film of an inorganic material such as indium tin oxide (ITO), tin oxide (SnO2), gold (Au) and the like and thin film of an organic material such as polyaniline, polythiophene and the like may be used.

As a material of the other electrode, heretofore known materials used in display devices may be used and, for example, a simple substance of metal, an alloy or a laminate thereof may be used. Such a metal is not particularly limited and for example in case of an organic EL device, magnesium (Mg), lithium (Li), calcium (Ca), silver (Ag), aluminum (Al), indium (In), cesium (Ce), copper (Cu), nickel (Ni) and lithium fluoride (LiF) may be used.

In the display device shown in FIGS. 1(a) and 1(b), the electro-optically functional film 12 may have a single layer structure or a laminated structure. When the electro-optically functional film 12 is an organic EL device, its suitable laminated structure includes, for example, a structure formed by laminating a hole injection and transport layer and a luminescent layer in succession, a structure formed by laminating a luminescent layer and an electron injection and transport layer in succession and a structure formed by laminating a hole injection and transport layer, a luminescent layer and an electron injection and transport layer in succession.

The luminescent layer may contain an electrical charge (an electron or a hole) transport material, an electrical charge injection material or an electrical charge restricting material, and includes, for example, a luminescent layer having an electron transporting property including an electron transport material. And the hole injection and transport layer may be divided into a hole injection layer and a hole transport layer, and the electron injection and transport layer may be divided into an electron injection layer and an electron transport layer. Luminescent materials including an emission assist (EA) agent, an electrical charge transport material, additives (donor or acceptor, etc.) and a luminous dopant also may be used for the above-mentioned luminescent layer.

As a luminescent material of such an luminescent layer, used may be heretofore known luminescent materials used in organic EL devices. As such a luminescent material, used may be a low molecular weight luminescent material, a high molecular weight (a polymer type) luminescent material or a precursor of a high molecular weight luminescent material each soluble in or dispersible in a solvent to be used, and the luminescent material may be one formed by combining two or more of these materials. As the above solvent, a solvent having a predetermined vapor pressure or boiling point may be selected from organic solvents containing an aromatic ring, and further another solvent may be added. An ink-jet printing device, dispenser or the like may be used for applying a solution of a composition.

<Step of Applying a Coating Liquid by Ink-Jet Printing Method>

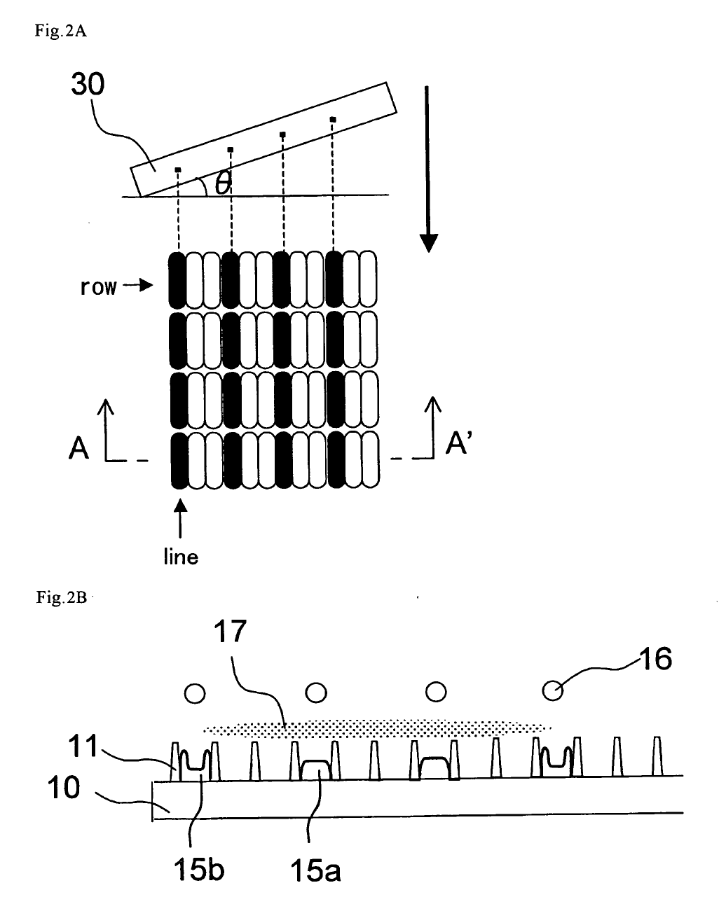

FIG. 2(a) schematically shows a state of applying a solution of a composition using an ink-jet printing device. The arrow in FIG. 2 indicates a moving direction of the ink-jet head 30 (head scan direction).

As shown in FIG. 2(a), since a nozzle spacing of the ink-jet head 30 is not consistent with a spacing of a device pattern, a solution of a composition is applied by inclining the ink-jet head 30 by an angle θ to align it with a position. Furthermore, when a long which can cover an effective area of a device by one scan, a desired nozzle spacing and a multi-nozzle head may not available, the head is moved to a raw direction by width applied (generally, an application of one block is completed by a plurality of scanning) and an operation of applying is repeated.

Furthermore, FIG. 2(b) is a cross sectional view schematically showing a color filter substrate shown in FIG. 2(a), taken on line A-A′, and shows a state in which a solvent of a high vapor pressure is applied onto the substrate. When a solvent having a high vapor pressure and starting to evaporate immediately after application as heretofore is used, a uniform and homogeneous film may not be produced, since a drying rate is slow in a central portion of the substrate and it is fast at an edge portion of a substrate as shown in FIG. 2(b).

<Production of a Functional Film and an Organic EL Device>

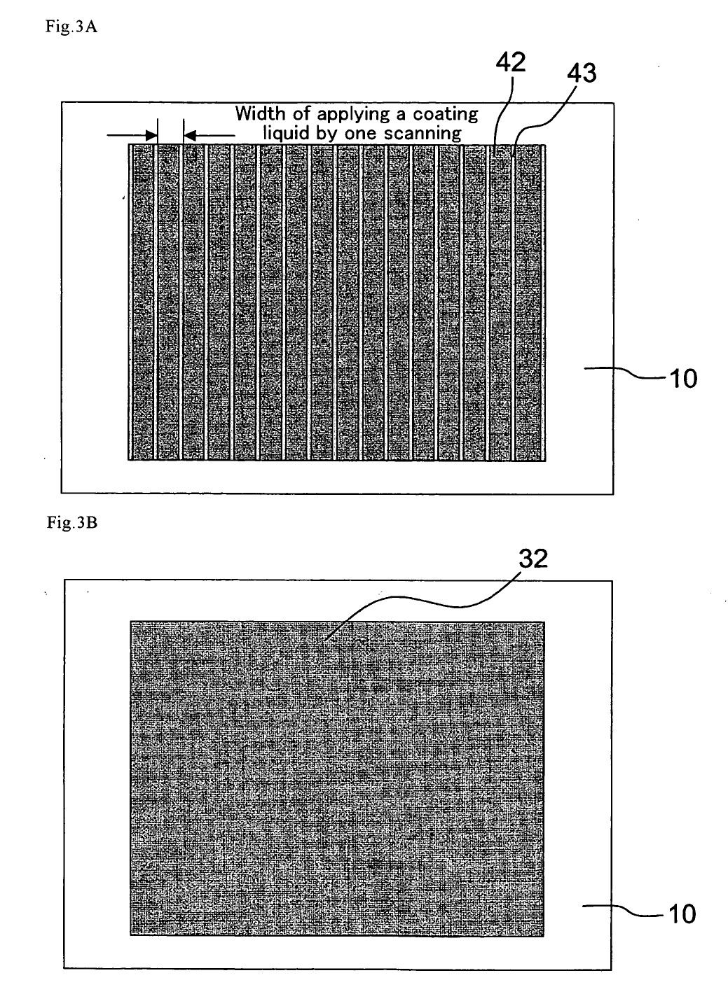

FIG. 3(a) is a schematic front view showing a photoluminescence (PL) pattern of a functional film prepared by a conventional method of producing a functional film. FIG. 3(b) is a schematic front view showing a photoluminescence (PL) pattern of a functional film prepared by a method of producing a functional film of the present invention.

The PL pattern shown in FIG. 3(a) is a pattern in using a solution of a composition containing a solvent with a high vapor and inconsistencies in density of a PL pattern corresponding to width of a coating liquid applied per 1 cycle of applying operations (a plurality of scanning) were clearly observed. In this case, since a distribution of film thickness is essentially attributed to air drying after the step of applying a coating liquid, and not to a step of drying or baking under properly reduced pressure.

On the other hand, in the PL pattern prepared from a method to which the step of drying under reduced pressure and further the step of baking are properly added using a solvent having a low vapor pressure, periodical unevenness corresponding to width of a coating liquid applied did not observed as shown in FIG. 3(b). Even though using a solvent having a low vapor pressure, when the solution of the composition does not undergo the step of drying under proper reduced pressure and the subsequent proper step of baking, the PL pattern essentially becomes like PL pattern shown in FIG. 3(a) though a degree of variations in film thickness and film quality is reduced.

The organic EL device prepared from the functional film having a microstructure shown in FIG. 3(b) can provide extremely uniform luminescence over the whole effective display area.

### PREFFERED EMBODIMENTS

Hereinafter, the present invention will be described in more detail using embodiments with reference to drawings, but the present invention is not limited to the embodiments.

### Embodiments 1 to 12

Using an ink-jet printing device, the solutions of a composition for a polymer type organic EL (the solutions of a composition for an ink-jet 1 to 6, viscosity: 5×10⁻³ to 10⁻² Pa.s, surface tension: 30 to 40 mN/m) shown in Table 2 were ejected at a rate of 8 picoliters per a droplet and applied in a pattern form and then subjected to drying under reduced pressure and baking under conditions shown in Table 3 to prepare a functional film. The drying under reduced pressure was carried out at a vacuum of 666 Pa. In Table 2, PDF represents polydioctylfluorene.

### Embodiments 13 to 15

Using an ink-jet printing device, the solutions of a composition for a polymer type organic EL (the solutions of a composition for an ink-jet 7 to 9, viscosity: 5×10⁻³ to 10⁻² Pa.s, surface tension: 30 to 40 mN/m) shown in Table 2 were ejected at a rate of 8 picoliters per a droplet and applied in a pattern form and then subjected to drying under reduced pressure and baking under conditions shown in Table 3 to prepare a functional film. The drying under reduced pressure was carried out at a vacuum of 666 Pa.

### COMPARATIVE EXAMPLES 1 TO 6

Using an ink-jet printing device, the solutions of a composition for a polymer type organic EL (the solutions of a composition for an ink-jet 1 to 6, viscosity: 5×10⁻³ to 10⁻² Pa.s, surface tension: 30 to 40 mN/m) shown in Table 2 were ejected at a rate of 8 picoliters per a droplet and applied in a pattern form and then subjected to baking without carrying out drying under reduced pressure as shown in Table 3 to prepare a functional film.

TABLE 6

| | Solvent | | |
|---|---|---|---|
| | | Vapor pressure | Solute |
| Solution of | | (25° C.) | (700 |
| a composition | Composition (mL) | Boiling point | mg) |
| 1 | tetralin (100) | 49.1 Pa, 207° C. | PDF |
| 2 | cyclohexylbenzene (80) | 240.1° C. | PDF |
| | xylene (20) | 2799.7 Pa, 140° C. | |
| 3 | diphenylmethane (70) | 48.1 Pa, 205° C. | PDF |
| | xylene (30) | 240.1° C. | |
| 4 | prehnitene (100) | 253 Pa, 165° C. | PDF |
| 5 | cyclohexylbenzene (70) | 1.01 Pa, 295° C. | PDF |
| | mesitylene (30) | 253 Pa, 165° C. | |
| 6 | phenyl sulfide (80) | PDF | |
| | mesitylene (20) | | |
| 7 | xylene (100) | 2799.7 Pa, 140° C. | PDF |
| 8 | cumene (100) | 1066.6 Pa, 152° C. | PDF |
| 9 | mesitylene (80) | 253 Pa, 165° C. | PDF |
| | xylene (20) | 2799.7 Pa, 140° C. | |

TABLE 3

| | | | | | | Uniformity of | Uniformity |
|---|---|---|---|---|---|---|---|
| | Solution | Drying under reduced pressure | | | | film thickness | of film |
| | of a | performed or | | Baking | | within film of | throughout |
| | composition | not performed | Temperature | Condition | Temperature | microstructure | device |
| Embodiment 1 | 1 | performed | 25° C. | under an inert gas atmosphere | 100° C. | excellent | excellent |
| Embodiment 2 | 2 | performed | 50° C. | under an inert gas atmosphere | 150° C. | excellent | excellent |
| Embodiment 3 | 3 | performed | 50° C. | under an inert gas atmosphere | 200° C. | excellent | excellent |
| Embodiment 4 | 1 | performed | 100° C. | under an inert gas atmosphere | 150° C. | good | good |
| Embodiment 5 | 2 | performed | 25° C. | under an inert gas atmosphere | 80° C. | good | good |
| Embodiment 6 | 3 | performed | 50° C. | under an inert gas atmosphere | 250° C. | good | good |
| Embodiment 7 | 4 | performed | 25° C. | under reduced pressure | 80° C. | excellent | excellent |
| Embodiment 8 | 5 | performed | 25° C. | under reduced pressure | 120° C. | excellent | excellent |
| Embodiment 9 | 6 | performed | 50° C. | under reduced pressure | 150° C. | excellent | excellent |
| Embodiment 10 | 4 | performed | 25° C. | under reduced pressure | 200° C. | good | good |
| Embodiment 11 | 5 | performed | 100° C. | under reduced pressure | 120° C. | good | good |
| Embodiment 12 | 6 | performed | 50° C. | under reduced pressure | 50° C. | good | good |
| Embodiment 13 | 7 | performed | 25° C. | under an inert gas atmosphere | 100° C. | good | good |
| Embodiment 14 | 8 | performed | 50° C. | under an inert gas atmosphere | 150° C. | good | good |
| Embodiment 15 | 9 | performed | 50° C. | under an inert gas atmosphere | 200° C. | good | good |
| Comparative Example 1 | 1 | not performed | — | under an inert gas atmosphere | 100° C. | poor | poor |
| Comparative Example 2 | 2 | not performed | — | under an inert gas atmosphere | 150° C. | poor | poor |
| Comparative Example 3 | 3 | not performed | — | under an inert gas atmosphere | 200° C. | poor | poor |
| Comparative Example 4 | 4 | not performed | — | under reduced pressure | 80° C. | poor | poor |
| Comparative Example 5 | 5 | not performed | — | under reduced pressure | 120° C. | poor | poor |
| Comparative Example 6 | 6 | not performed | — | under reduced pressure | 150° C. | poor | poor |

<Evaluation of Uniformity of Film Thickness>

Functional films prepared in Embodiments 1 to 15 and Comparative Examples 1 to 6 were measured for cross-sectional profiles using a surface shape measuring apparatus and the uniformity of the film thickness was respectively evaluated. The functional films were also measured for distributions of luminance of PL (photoluminescence) using a CCD camera and the uniformity of the film throughout the device were respectively evaluated. The results are shown in Table 3.

As shown in Table 2, the solutions of a composition 1 to 6 contain at least one solvent having a vapor pressure of 0.133 to 133 Pa at 25° C. and a boiling point of 200 to 300° C. under atmospheric pressure. Accordingly, in Embodiments 1 to 12 in which these solutions were used and drying under reduced pressure were performed, uniform and homogeneous functional films could be obtained in the films having a microstructure and in the whole device as shown in Table 3. Among others, in Embodiments 1 to 3 and7 to 9, since the conditions of drying under reduced pressure and baking were optimized depending on the solution of a composition, particularly uniform and homogeneous functional films could be obtained.

And, in Embodiments 13 to 15, since the solutions of a composition did not contain the solvents having an optimal physical property for obtaining effect of the present invention, uniform and homogeneous functional films could not be formed so much as in Embodiments 1 to 3 and 7 to 9 in spite of drying under reduced pressure. Furthermore, in Comparative Examples 1 to 6, since no drying under reduced pressure was performed, uniform and homogeneous functional films could not be formed although the solutions of a composition satisfied the condition on solvent physical properties for obtaining effect of the present invention.

What is claimed is:

1. A method of producing a functional film formed in a pattern form on a substrate by a wet process,
said method of producing a functional film comprising the steps of:
applying a solution formed by one of dissolving and dispersing a functional material in a solvent to a substrate;
removing the solvent under reduced pressure; and
baking the functional material under one of an inert gas atmosphere and reduced pressure in this order.

2. The method of producing a functional film according to claim 1, wherein said solvent contains at least one organic solvent with an aromatic ring having a vapor pressure of 0.133 Pa or higher and 133 Pa or lower at 25° C.

3. The method of producing a functional film according to claim 1, wherein said solvent contains at least one organic solvent with an aromatic ring having a boiling point of 200° C. or higher and 300° C. or lower under atmospheric pressure.

4. The method of producing a functional film according to claim 1, wherein said substrate is provided with a hydrophilic-hydrophobic contrast pattern.

5. The method of producing a functional film according to claim 4, wherein the shortest interval of the hydrophilic-hydrophobic contrast patterns on said substrate is 25 μm or larger and 50 μm or smaller.

6. The method of producing a functional film according to claim 1, wherein said substrate is provided with a pattern partitioned with an isolating wall and the isolating wall is hydrophobic and inside of the pattern partitioned with the isolating wall is hydrophilic.

7. The method of producing a functional film according to claim 6, wherein the shortest interval of the patterns partitioned with the isolating wall in said substrate is 25 μm or larger and 50 μm or smaller.

8. The method of producing a functional film according to claim 1, wherein said step of applying the solution is a step in which the solution is applied with an ink-jet printing device and a minimum amount of an ejected droplet of the solution applied is 2 picoliters or more and 10 picoliters or less.

9. The method of producing a functional film according to claim 1, wherein said step of removing the solvent is carried out in a vacuum of 13.3 Pa or higher and 1332 Pa or lower and at a treatment temperature of 20° C. or higher and 60° C. or lower.

10. The method of producing a functional film according to claim 1, wherein said step of baking the functional material is carried out at a treatment temperature of 100° C. or higher and 200° C. or lower under an inert gas atmosphere.

11. The method of producing a functional film according to claim 1, wherein said step of baking the functional material is carried out at a treatment temperature of 80° C. or higher and 150° C. or lower under reduced pressure.

12. A coating liquid for forming a functional film, formed by one of dissolving and dispersing a functional material in a solvent, wherein said solvent contains at least one organic solvent with an aromatic ring having a vapor pressure of 0.133 Pa or higher and 133 Pa or lower at 25° C.

13. A coating liquid for forming a functional film, formed by one of dissolving and dispersing a functional material in a solvent, wherein said solvent contains at least one organic solvent with an aromatic ring having a boiling point of 200° C. or higher and 300° C. or lower under atmospheric pressure.

14. A functional device, comprising a functional film produced by the method of producing a functional film according to claim 1.

15. A functional device, comprising a functional film formed by using the coating liquid for forming a functional film according to claim 12.

16. A functional device, comprising a functional film formed by using the coating liquid for forming a functional film according to claim 13.

17. An electron device formed by mounting the functional device according to claim 14.

18. An electron device formed by mounting the functional device according to claim 15.

19. An electron device formed by mounting the functional device according to claim 16.

20. A display device formed by mounting the functional device according to claim 14.

21. A display device formed by mounting the functional device according to claim 15.

22. A display device formed by mounting the functional device according to claim 16.
